(19) United States
(12) Patent Application Publication
(10) Pub. No.: US 2016/0336077 A1
(43) Pub. Date: Nov. 17, 2016

(54) SEMICONDUCTOR DEVICE AND SEMICONDUCTOR SYSTEM

(71) Applicant: SK hynix Inc., Icheon-si Gyeonggi-do (KR)

(72) Inventor: Young Kyu NOH, Seongnam-si Gyeonggi-do (KR)

(21) Appl. No.: 14/808,716

(22) Filed: Jul. 24, 2015

(30) Foreign Application Priority Data
May 11, 2015 (KR) 10-2015-0065619

(51) Int. Cl. G11C 17/16; G11C 29/04; G06F 9/44; G11C 17/18

(52) U.S. Cl. CPC G11C 17/16; G11C 17/18; G11C 29/04; G06F 9/4403

(57) ABSTRACT

A semiconductor system includes a controller configured to generate a boot-up signal; and a semiconductor device configured to, if addresses, which increase by a predetermined value, have the same combination of bits as fuse data, initialize fuse data in response to the boot-up signal or a reset signal, and generate the fuse data by using latched internal fuse data after the fuse data are initialized.

### CROSS-REFERENCE TO RELATED APPLICATION

The present application claims priority under 35 U.S.C. §119(a) to Korean application number 10-2015-0065619 filed on May 11, 2015, in the Korean Intellectual Property Office, which is incorporated herein by reference in its entirety.

### BACKGROUND

1. Technical Field

Embodiments of the present disclosure generally relate to an integrated circuit and an electronic system, and more particularly to a semiconductor device and a semiconductor system.

2. Related Art

In semiconductor devices, fuses are used to store information necessary for various internal control operations, such as setting information, repair information and so forth. The information in conventional fuses can be read by detecting whether the fuses have been cut by a laser or not. The conventional fuses are programmed while the semiconductor devices are in the form of a wafer, and thus once a package process has been completed, it is impossible to program conventional fuses. Recent developments in fuses are leading to advances in e-fuses. The e-fuses are electronic fuses that store information by changing the resistance between a gate and a drain/source of a transistor. Unlike the conventional fuses, e-fuse can be programmed even after the package process has been completed.

The information stored in the e-fuse can be read without separate sensing operations by increasing the size of the transistor. The information stored in the e-fuse can also be read by sensing the current flowing through the transistor. This method can reduce the size of the transistor, but amplifiers are necessary. These two methods have limitations in terms of area because it is necessary to have larger transistors or additional amplifiers.

Recently, various proposals have been made to cope with the limitations to the e-fuses. One of them is e-fuses in the form of an array. In this case, since amplifiers for e-fuses may be shared, the whole area of the semiconductor device may be decreased.

### SUMMARY

Various embodiments are directed to a semiconductor device and a semiconductor system which generate fuse data after the initialization operation of a fuse latch for generating fuse data is completed in the case where the fuse latch is not initialized in a boot-up operation.

In an embodiment, a semiconductor system may include: a controller configured to generate a boot-up signal; and a semiconductor device configured to initialize fuse data in the case where addresses sequentially counted and the fuse data are the same combination, in response to the boot-up signal or a reset signal, and generate the fuse data by latching internal fuse data after the fuse data are initialized.

In an embodiment, a semiconductor device may include: a command generation block configured to generate first and second test commands in response to a boot-up signal which is enabled upon entry to a boot-up operation or a reset signal, and generate first and second internal commands in response to the boot-up signal or the reset signal; an address generation block configured to generate addresses which are sequentially counted, in response to the boot-up signal or the reset signal; a comparison signal generation block configured to compare the addresses and fuse data in response to the first and second test commands, and generate a comparison signal which is enabled in the case where a combination of the addresses and a combination of the fuse data are the same combination; and a fuse block configured to generate a control signal which is enabled in response to the comparison signal, initialize the fuse data in response to the reset signal, and generate the fuse data by latching internal fuse data in response to the first and second internal commands.

In an embodiment, an initialization method may include: a boot-up operation entering action of generating a boot-up signal upon entry to a boot-up operation; a command generating action of generating first and second test commands in response to the boot-up signal; an address increasing action of generating addresses which are sequentially counted, in response to the boot-up signal; an address comparing action of comparing the addresses and fuse data in response to the first and second test commands, and generating a comparison signal which is enabled in the case where a combination of the addresses and a combination of the fuse data are the same combination; and an initialization condition changing action of generating a control signal which is enabled in response to the comparison signal, and initializing the fuse data in response to a reset signal.

According to the embodiments, in the case where a fuse latch for generating fuse data is not initialized in a boot-up operation, fuse data are generated after the initialization operation of the fuse latch is completed, whereby it is possible to secure the reliability of fuse data.

### BRIEF DESCRIPTION OF THE DRAWINGS

FIG. 1 is a block diagram illustrating a configuration example of a semiconductor system in accordance with an embodiment.

FIG. 2 is a block diagram illustrating a configuration example of the comparison signal generation block included in the semiconductor device shown in FIG. 1.

FIG. 3 is a circuit diagram illustrating an example of the logic unit included in the comparison signal generation block shown in FIG. 2.

FIG. 4 is a block diagram illustrating a configuration example of the fuse data generation unit included in the fuse block shown in FIG. 1.

FIG. 5 is a representation of an example of a flow chart to explain the operation of the semiconductor system in accordance with an embodiment.

FIG. 6 is a block diagram illustrating a configuration example of a semiconductor system in accordance with an embodiment.

### DETAILED DESCRIPTION

Hereinafter, a semiconductor device and a semiconductor system will be described below with reference to the accompanying drawings through various examples of embodiments.

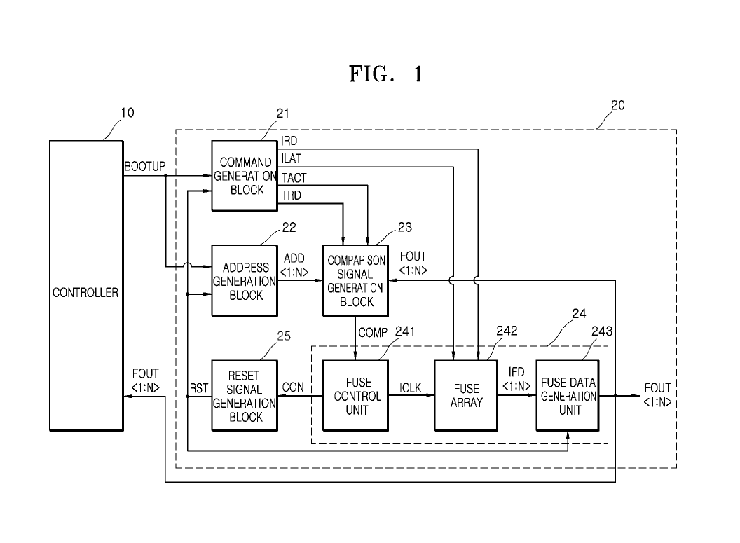

As shown in FIG. 1, a semiconductor system in accordance with an embodiment may include a controller 10 and a semiconductor device 20. The semiconductor device 20 may include a command generation block 21, an address generation block 22, a comparison signal generation block 23, a fuse block 24, and a reset signal generation block 25.

The controller 10 may generate a boot-up signal BOOTUP which is enabled upon entry to a boot-up operation. The boot-up operation is an operation of sequentially outputting the information generated from an e-fuse array.

The controller 10 may be inputted with first to Nth fuse data FOUT<1:N> in the boot-up operation and thereby obtain information necessary for the internal control operations of the semiconductor device 20.

The command generation block 21 may generate a first test command TACT and a second test command TRD, which are sequentially generated, in response to the boot-up signal BOOTUP or a reset signal RST. The command generation block 21 may also generate a first internal command IRD and a second internal command ILAT, which are sequentially generated, in response to the boot-up signal BOOTUP or the reset signal RST. The reset signal RST is a signal which is enabled in the case where first to Nth addresses ADD<1:N> and the first to Nth fuse data FOUT<1:N> have the same combination of bits. An operation of generating the reset signal RST will be described later in detail through a configuration which is to be described later.

The address generation block 22 may generate the first to Nth addresses ADD<1:N> in response to the boot-up signal BOOTUP or the reset signal RST. For example, the address generation block 22 may include an address counter that increases address values by a predetermined value. For example, the address generation block 22 may generate the first to Nth addresses ADD<1:N>, each bit of which has a logic low level, when the boot-up signal BOOTUP or the reset signal RST is inputted thereto, and may increase the first to Nth addresses ADD<1:N> up to the address each bit of which has a logic high level.

The comparison signal generation block 23 may compare the first to Nth addresses ADD<1:N> and the first to Nth fuse data FOUT<1:N> in response to the first test command TACT and the second test command TRD, and generate a comparison signal COMP which is enabled in the case where the first to Nth addresses ADD<1:N> and the first to Nth fuse data FOUT<1:N> have the same combination of bits.

The fuse block 24 may include a fuse control unit 241, a fuse array 242 and a fuse data generation unit 243.

The fuse control unit 241 may generate a control signal CON which is enabled in response to the comparison signal COMP, and generate an internal clock ICLK which periodically toggles.

The fuse array 242 may include a plurality of fuse cells (not shown), and generate first to Nth internal fuse data IFD<1:N> according to whether the plurality of fuse cells are cut or not. The fuse array 242 may generate first to Nth internal fuse data IFD<1:N>, which are synchronized with the internal clock ICLK, in response to the first internal command IRD and the second internal command ILAT. In the fuse array 242 may include e-fuses.

The fuse data generation unit 243 may generate, before initialization, the first to Nth fuse data FOUT<1:N>, initialize the first to Nth fuse data FOUT<1:N> in response to the reset signal RST, and, after initialization, generate the first to Nth fuse data FOUT<1:N> by using latched first to Nth internal fuse data IFD<1:N>.

The reset signal generation block 25 may generate the reset signal RST which is enabled in response to the control signal CON.

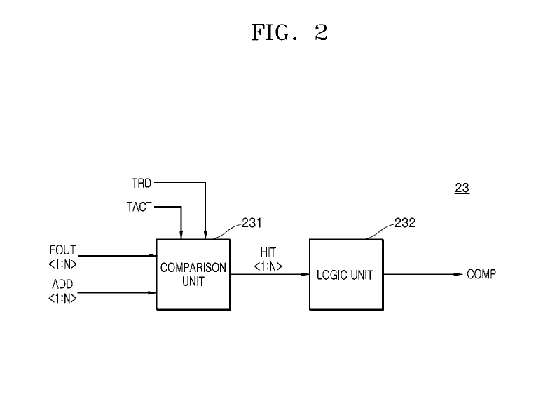

Referring to FIG. 2, the comparison signal generation block 23 may include a comparison unit 231 and a logic unit 232.

In the case where the bits of the first to Nth addresses ADD<1:N> and the first to Nth fuse data FOUT<1:N> are the same, the comparison unit 231 may generate first to Nth comparison codes HIT<1:N> which are enabled to a logic high level in response to the first test command TACT and the second test command TRD. In the case where the first test command TACT is inputted, the comparison unit 231 may recognize the first to Nth addresses ADD<1:N> as row addresses. In the case where the second test command TRD is inputted, the comparison unit 231 may recognize the first to Nth addresses ADD<1:N> as column addresses.

In the case where the first to Nth comparison codes HIT<1:N> have the combination of bits as a preset combination of bits, the logic unit 232 may generate the comparison signal COMP which is enabled. For example, each bit of the first to Nth comparison codes HIT<1:N> may be preset to the logic high level.

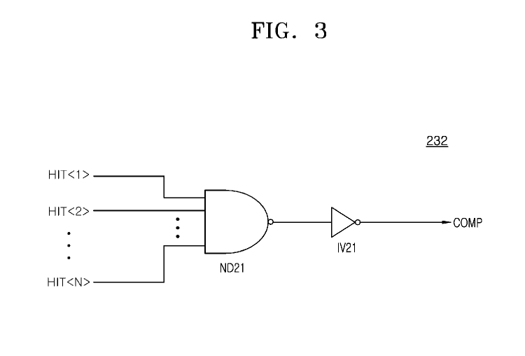

Referring to FIG. 3, the logic unit 232 may include a NAND gate ND21 and an inverter IV21.

The NAND gate ND21 may generate an output signal by performing a NAND operation on the first to Nth comparison codes HIT<1:N>.

The inverter IV21 may generate the comparison signal COMP by inverting the output signal of the NAND gate ND21.

In the case where the first to Nth comparison codes HIT<1:N> has the same combination of bits as the preset combination of bits, the logic unit 232 in accordance with an embodiment may generate the comparison signal COMP as follows.

The NAND gate ND21 generates the output signal of a logic low level in response to the first to Nth comparison codes HIT<1: N> each bit of which has the logic high level.

The inverter IV21 generates the comparison signal COMP which is enabled to a logic high level by inverting the output signal of the NAND gate ND21.

That is to say, the logic unit 232 may generate the comparison signal COMP which is enabled to the logic high level in response to the first to Nth comparison codes HIT<1:N> each of which has the logic high level, which is the same as the preset combination of bits.

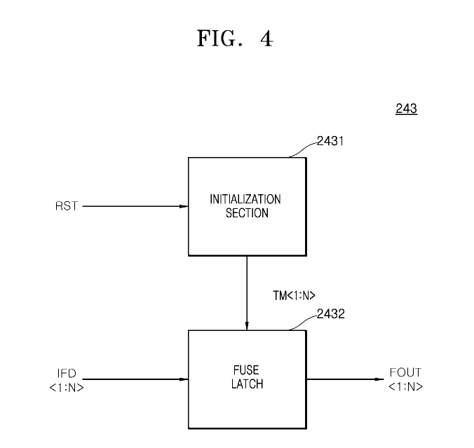

Referring to FIG. 4, the fuse data generation unit 243 may include an initialization section 2431 and a fuse latch 2432.

The initialization section 2431 may generate first to Nth test mode signals TM<1:N> in response to the reset signal RST. The initialization section 2431 may include a register, and may generate the first to Nth test mode signals TM<1:N>.

The fuse latch 2432 may generate the first to Nth fuse data FOUT<1:N> before initialization, and generate the first to Nth fuse data FOUT<1:N>, the combination of which is the same as a preset combination of bits, by performing an initialization operation in which the level of the voltage supplied thereto is controlled in response to the first to Nth test mode signals TM<1:N>. After the initialization. the fuse latch 2432 may generate the first to Nth fuse data FOUT<1:N> by using latched first to Nth internal fuse data IFD<1:N>. The initialization of the fuse latch 2432 may include an operation of generating the first to Nth fuse data FOUT<1:N> each bit of which has a logic low level by controlling the level of the supplied voltage. Also, the first to Nth fuse data FOUT<1:N>, the combination of which is the same as the preset combination, may mean that all the bits of the first to Nth fuse data FOUT<1:N> have the logic low levels. However, the present combination of bits is not limited thereto, and thus the preset combination may be set such that all the bits of the first to Nth fuse data FOUT<1:N> have logic high levels.

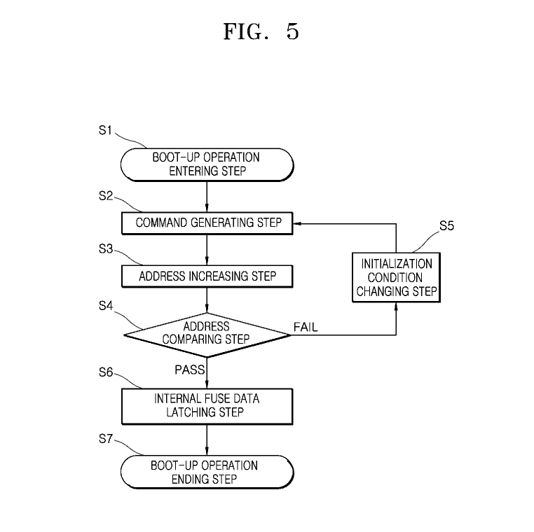

Operations of the semiconductor system in accordance with an embodiment will be described below with reference to FIG. 5 with respect to a situation where the first to Nth fuse data FOUT<1:N> are generated after the initialization operation is completed in the case where the fuse latch 2432 is not initialized upon entry to the boot-up mode.

In a boot-up operation entering step S1, the controller 10 generates the boot-up signal BOOTUP which is enabled upon entry to the boot-up operation.

In a command generating step S2, the command generation block 21 generates the first test command TACT and the second test command TRD, which are sequentially enabled, in response to the boot-up signal BOOTUP.

In an address increasing step S3, the address generation block 22 generates the first to Nth addresses ADD<1:N>, the address value of which increases by a predetermined value, in response to the boot-up signal BOOTUP. The address generation block 22 increases address values of the first to Nth addresses ADD<1:N> by a predetermined value from a combination in which all the bits of the first to Nth addresses ADD<1:N> are the logic low level to a combination in which all the bits of the first to Nth addresses ADD<1:N> are the logic high level.

In an address comparing step S4, the comparison signal generation block 23 compares the first to Nth addresses ADD<1:N> and the first to Nth fuse data FOUT<1:N> in response to the first test command TACT and the second test command TRD, and generates the comparison signal COMP of the logic high level, which represents a fail FAIL since the fuse latch 2432 is not initialized and thus all the bits of the first to Nth fuse data FOUT<1:N> are not generated as the logic low level.

In an initialization condition changing step S5, the fuse control unit 241 of the fuse block 24 generates the control signal CON of a logic high level in response to the comparison signal COMP of the logic high level.

The reset signal generation block 25 generates the reset signal RST of a logic high level in response to the control signal CON of the logic high level.

The initialization section 2431 of the fuse data generation unit 243 generates the first to Nth test mode signals TM<1:N> in response to the reset signal RST of the logic high level.

The fuse latch 2432 of the fuse data generation unit 243 is inputted with the first to Nth test mode signals TM<1:N>. The fuse latch 2432 generates the first to Nth fuse data FOUT<1:N>, each bit of which is initialized to the logic low level, by controlling the voltage supplied thereto in response to the first to Nth test mode signals TM<1:N>.

The command generation block 21 generates the first test command TACT and the second test command TRD which are sequentially enabled, and generates the first internal command IRD and the second internal command ILAT in response to the reset signal RST. That is to say, entry to the command generating step S2 is made again.

The address generation block 22 generates the first to Nth addresses ADD<1:N>, the address value of which increases by a predetermined value, in response to the reset signal RST. The address generation block 22 increases address values of the first to Nth addresses ADD<1:N> by a predetermined value from the combination in which all the bits of the first to Nth addresses ADD<1:N> are the logic low level to the combination in which all the bits of the first to Nth addresses ADD<1:N> are the logic high level. That is to say, entry to the address increasing step S3 is made again.

The comparison signal generation block 23 compares the first to Nth addresses ADD<1:N> and the first to Nth fuse data FOUT<1:N> in response to the first test command TACT and the second test command TRD, and generates the comparison signal COMP of a logic low level, which represents a pass PASS since the fuse latch 2432 is initialized and thus all the bits of the first to Nth fuse data FOUT<1:N> are generated as the logic low level. That is to say, entry to the address comparing step S4 is made again.

when a fail FAIL occurs in the address comparing step S4, the command generating step S2, the address increasing step S3 and the address comparing step S4 are repeatedly performed until the address comparing step S4 is recognized as a pass PASS.

In an internal fuse data latching step S6, the fuse control unit 241 of the fuse block 24 is inputted with the comparison signal COMP of the logic low level, generates the control signal CON of a logic low level, and generates the internal clock ICLK which periodically toggles.

The fuse array 242 of the fuse block 24 generates the first to Nth internal fuse data IFD<1:N>, which are synchronized with the internal clock ICLK, in response to the first internal command IRD and the second internal command ILAT.

The fuse data generation unit 243 of the fuse block 24 generates the first to Nth fuse data FOUT<1:N> by using latched first to Nth internal fuse data IFD<1:N>.

The reset signal generation block 25 generates the reset signal RST, which is disabled to a logic low level, in response to the control signal CON of the logic low level.

In a boot-up operation ending step S7, the fuse data generation unit 243 of the fuse block 24 outputs the first to Nth fuse data FOUT<1:N>.

In the semiconductor system in accordance with the embodiment configured as mentioned above, in the case where the fuse latch is not initialized in a boot-up operation, fuse data are generated after the initialization operation of a fuse latch, and thus the reliability of fuse data may be secured.

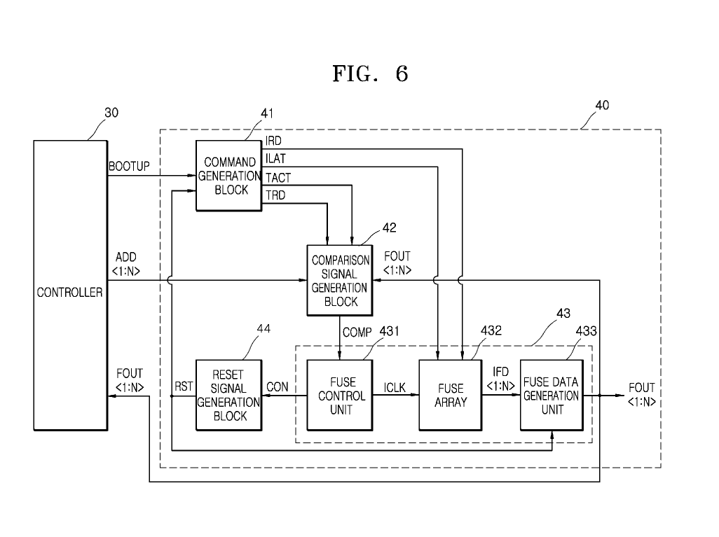

FIG. 6 is a block diagram illustrating a configuration example of a semiconductor system in accordance with an embodiment.

As shown in FIG. 6, a semiconductor system in accordance with an embodiment may include a controller 30 and a semiconductor device 40. The semiconductor device 40 may include a command generation block 41, a comparison signal generation block 42, a fuse block 43, and a reset signal generation block 44.

The controller 30 may generate a boot-up signal BOOTUP which is enabled upon entry to a boot-up operation, and generate first to Nth addresses ADD<1:N> the address value of which increases by a predetermined value. The boot-up operation is an operation of sequentially outputting the information generated from an e-fuse array.

The controller 30 may be inputted with first to Nth fuse data FOUT<1:N> in the boot-up operation and thereby obtain information necessary for the internal control operations of the semiconductor device 40.

The command generation block 41 may generate a first test command TACT and a second test command TRD, which are sequentially generated, in response to the boot-up signal BOOTUP or a reset signal RST. The command generation block 41 may also generate a first internal command IRD and a second internal command ILAT, which are sequentially generated, in response to the boot-up signal BOOTUP or the reset signal RST. The reset signal RST is a signal which is enabled in the case where first to Nth addresses ADD<1:N> and the first to Nth fuse data FOUT<1:N> have the same combination of bits.

The comparison signal generation block 42 may compare the first to Nth addresses ADD<1:N> and the first to Nth fuse data FOUT<1:N> in response to the first test command TACT and the second test command TRD, and generate a comparison signal COMP which is enabled in the case where the first to Nth addresses ADD<1:N> and the first to Nth fuse data FOUT<1:N> have the same combination of bits.

The fuse block 43 may include a fuse control unit 431, a fuse array 432 and a fuse data generation unit 433.

The fuse control unit 431 may generate a control signal CON which is enabled in response to the comparison signal COMP, and generate an internal clock ICLK which periodically toggles.

The fuse array 432 may include a plurality of fuse cells (not shown), and generate first to Nth internal fuse data IFD<1: N> according to whether the plurality of fuse cells are cut or not. The fuse array 432 may generate first to Nth internal fuse data IFD<1:N>, which are synchronized with the internal clock ICLK, in response to the first internal command IRD and the second internal command ILAT. In the fuse array 432 may include e-fuses.

The fuse data generation unit 433 may generate, before initialization, the first to Nth fuse data FOUT<1:N>, initialize the first to Nth fuse data FOUT<1:N> in response to the reset signal RST, and, after initialization, generate the first to Nth fuse data FOUT<1:N> by using latched first to Nth internal fuse data IFD<1:N>.

The reset signal generation block 44 may generate the reset signal RST which is enabled in response to the control signal CON. Since the components of the semiconductor device 40 shown in FIG. 6 are realized by the same circuits as the components of the semiconductor device 20 shown in FIG. 1, further detailed descriptions thereof will be omitted herein.

In the semiconductor system in accordance with the embodiment configured as mentioned above, in the case where the fuse latch is not initialized in a boot-up operation, fuse data are generated after the initialization operation of a fuse latch, and thus the reliability of fuse data may be secured.

While various embodiments have been described above, it will be understood to those skilled in the art that the embodiments described are by way of example only. Accordingly, the semiconductor device and the semiconductor system described herein should not be limited based on the described embodiments.

1. A semiconductor system comprising:
a controller configured to generate a boot-up signal; and
a semiconductor device configured to, if addresses, which increase by a predetermined value, have a same combination of bits as fuse data, initialize fuse data in response to the boot-up signal or a reset signal, and generate the fuse data by using latched internal fuse data after the fuse data are initialized,
wherein the fuse data are initialized to a preset combination of bits if they are initialized in a boot-up operation, and
wherein the preset combination of bits are generated all same logic level by controlling a level of a supplied voltage.

2. The semiconductor system according to claim 1, wherein the reset signal is a signal which is enabled if the addresses and the fuse data have the same combination of bits.

3. (canceled)

4. The semiconductor system according to claim 1, wherein the semiconductor device comprises:
a command generation block configured to generate first and second test commands in response to the boot-up signal or the reset signal, and generate first and second internal commands in response to the boot-up signal or the reset signal;
an address generation block configured to generate the addresses, which increase by a predetermined value, in response to the boot-up signal or the reset signal;
a comparison signal generation block configured to compare the fuse data and the addresses in response to the first and second test commands, and generate a comparison signal which is enabled if the addresses and the fuse data have the same combination of bits; and
a fuse block configured to generate a control signal which is enabled in response to the comparison signal, initialize the fuse data in response to the reset signal, and generate the fuse data by using latched internal fuse data in response to the first and second internal commands.

5. The semiconductor system according to claim 4, further comprising:
a reset signal generation block configured to generate the reset signal which is enabled in response to the control signal.

6. The semiconductor system according to claim 4, wherein the comparison signal generation block comprises:
a comparison unit configured to generate comparison codes, which are enabled if a combination of bits of the addresses and the fuse data are the same, in response to the first and second test commands; and
a logic unit configured to generate the comparison signal which is enabled if the comparison codes are a preset combination of bits.

7. The semiconductor system according to claim 4, wherein the fuse block comprises:
a fuse control unit configured to generate the control signal which is enabled in response to the comparison signal, and generate an internal clock which periodically toggles;
a fuse array including a plurality of fuse cells, the fuse array configured to generate, in response to the first and second internal commands, the internal fuse data according to whether the plurality of fuse cells are cut or not, wherein the internal fuse data is synchronized with the internal clock; and
a fuse data generation unit configured to generate the fuse data before initialization, initialize the fuse data in response to the reset signal, and, after the initialization, generate the fuse data by using the latched internal fuse data.

8. The semiconductor system according to claim 7, wherein the fuse data generation unit comprises:
an initialization section configured to generate a plurality of test mode signals in response to the reset signal; and
a fuse latch configured to be initialized in response to the plurality of test mode signals, and generate the fuse data by using the latched internal fuse data after the initialization.

9. The semiconductor system according to claim 8, wherein the fuse latch is initialized by controlling a level of a voltage supplied to the plurality of fuse cells according to the plurality of test mode signals.

10. A semiconductor device comprising:
a command generation block configured to generate first and second test commands in response to a boot-up signal which is enabled upon entry to a boot-up operation or a reset signal, and generate first and second internal commands in response to the boot-up signal or the reset signal;
an address generation block configured to generate addresses, which increase by a predetermined value, in response to the boot-up signal or the reset signal;
a comparison signal generation block configured to compare the addresses and fuse data in response to the first and second test commands, and generate a comparison signal which is enabled if the addresses and the fuse data have a same combination of bits; and
a fuse block configured to generate a control signal which is enabled in response to the comparison signal, initialize the fuse data in response to the reset signal, and generate the fuse data by using latched internal fuse data in response to the first and second internal commands,
wherein the fuse data are initialized to a preset combination of bits if they are initialized in the boot-up operation, and
wherein the preset combination of bits are generated all same logic level by controlling a level of a supplied voltage.

11. The semiconductor device according to claim 10, wherein the reset signal is a signal which is enabled if the addresses and the fuse data have the same combination of bits.

12. (canceled)

13. The semiconductor device according to claim 10, further comprising:
a reset signal generation block configured to generate the reset signal which is enabled in response to the control signal.

14. The semiconductor device according to claim 10, wherein the comparison signal generation block comprises:
a comparison unit configured to generate comparison codes, which are enabled if a combination of bits of the addresses and the fuse data are the same, in response to the first and second test commands; and
a logic unit configured to generate the comparison signal which is enabled if the comparison codes are a preset combination of bits.

15. The semiconductor device according to claim 10, wherein the fuse block comprises:
a fuse control unit configured to generate the control signal which is enabled in response to the comparison signal, and generate an internal clock which periodically toggles;
a fuse array including a plurality of fuse cells, the fuse array configured to generate, in response to the first and second internal commands, the internal fuse data according to whether the plurality of fuse cells are cut or not, wherein the internal fuse data is synchronized with the internal clock; and
a fuse data generation unit configured to generate the fuse data before initialization, initialize the fuse data in response to the reset signal, and, after the initialization, generate the fuse data by using the latched internal fuse data.

16. The semiconductor device according to claim 15, wherein the fuse data generation unit comprises:
an initialization section configured to generate a plurality of test mode signals in response to the reset signal; and
a fuse latch configured to be initialized in response to the plurality of test mode signals, and generate the fuse data by using the latched internal fuse data after the initialization.

17. The semiconductor device according to claim 16, wherein the fuse latch is initialized by controlling a level of a voltage supplied to the plurality of fuse cells according to the plurality of test mode signals.

18. An initialization method comprising:
a boot-up operation entering step of generating a boot-up signal upon entry to a boot-up operation;
a command generating step of generating first and second test commands in response to the boot-up signal;
an address increasing step of generating addresses, which increase by a predetermined value, in response to the boot-up signal;
an address comparing step of comparing the addresses and fuse data in response to the first and second test commands, and generating a comparison signal which is enabled if the addresses has a same combination of bits as the fuse data; and
an initialization condition changing step of generating a control signal which is enabled in response to the comparison signal, and initializing the fuse data in response to a reset signal,
wherein the fuse data are initialized to a preset combination if they are initialized according to a plurality of test mode signals which are generated in response to the reset signal, and
wherein the preset combination of bits are generated all same logic level by controlling a level of a supplied voltage.

19. The initialization method according to claim 18, wherein the reset signal is a signal which is enabled if the addresses and the fuse data have the same combination of bits.

20. (canceled)

21. The initialization method according to claim 18, wherein, in the case of initializing the fuse data, a level of a voltage supplied to a plurality of fuse cells which generate the fuse data is controlled according to the plurality of test mode signals.

22. The initialization method according to claim 18, wherein the command generating step comprises generating first and second internal commands in response to the reset signal.

23. The initialization method according to claim 18, wherein the address increasing action comprises generating the addresses, which increase by a predetermined value, in response to the reset signal.

24. The initialization method according to claim 18, further comprising:
an internal fuse data latching step of comparing the addresses and fuse data in response to the first and second internal commands, and generating the fuse data by using latched internal fuse data if the addresses have different combination of bits than the fuse data; and
a boot-up operation ending step of outputting the fuse data to an exterior.
